(19) United States
(12) Patent Application Publication
(10) Pub. No.: US 2007/0215946 A1
(43) Pub. Date: Sep. 20, 2007

(54) Broadband communications system via reflection from artificial ionized plasma patterns in the atmosphere

(76) Inventor: Bernard John Eastlund, Saint Louis, MO (US)

Correspondence Address: BERNARD EASTLAND, 13414 TIVER TON RD., SAN DIEGO, CA, 92130, US

(21) Appl. No.: 11/716,175

(22) Filed: Mar. 10, 2007

Related U.S. Application Data
(60) Provisional application No. 60/782,085, filed on Mar. 14, 2006.

(51) Int. Cl. H01L 27/01

(52) U.S. Cl. 257/349

(57) ABSTRACT

A new communications system is described in which the phased array heater used to create an artificial ionized plasma pattern in the atmosphere (AIPA) has an integrated phased array transmitter. By combining these two functions a simplified telecommunications system is created. The new system is called the Integrated Plasma Mirror. Another advantage is that a portion of the telecommunications signal is absorbed in the plasma pattern and contributes to the maintenance power level.

### CROSS REFERENCE TO RELATED APPLICATIONS:

This patent application is related to Provisional Patent Application 60/782,085 filed on Mar. 14, 2006.

### BACKGROUND OF THE INVENTION

1. Field of Invention

This invention generally relates to telecommunications utilizing an electromagnetic wave reflecting artificial ionized plasma mirror in the atmosphere

2. Prior Art

Bernard J. Eastlund describes cosmic ray particle ignition in method and apparatus U.S. patent application Ser. No. 11/219,982 filed Sep. 6, 2005 and in a white paper entitled, “Cosmic Ray Ignition of Artificial Ionized Plasma Patterns in the Atmosphere (AIPA)”, Jan. 12, 2006. The communications concepts described in those documents have an electromagnetic phased array heater beam for forming an artificial ionized plasma pattern in the atmosphere, and separate telecommunications base stations and receivers to utilize the artificial ionized layer.

### BACKGROUND OF THE INVENTION—OBJECTIVES

The objective of this invention is to describe a principal new innovation referred to herein as the Integrated Plasma Mirror (IPM) which combines the base station with the phased array heater in a single system to provide a simplified system that has many advantages for telecommunications.

Another objective is to have the telecommunications signal power contribute to the power required to maintain the artificial ionized plasma layer.

### SUMMARY

This invention is for a broadband communications system based on reflections of electromagnetic signals from artificial ionized plasma patterns in the atmosphere. (AIPA). The system utilizes the novel method of using cosmic particles (cosmic ray showers or micro-meteorite trails) to ignite artificial ionized plasma patterns in the atmosphere with phased array heater at power levels that are much lower than the levels assumed in previous studies The novel method assumes that an electromagnetic wave heater breaks down the atmosphere to create an ionization layer and that an up-link is provided by a separate base station that directs communication signals towards the AIPA which is referred to as a plasma mirror (PM) that reflects the signals to provide the down-link to a remote receiver.

A principal embodiment of invention is to which combines the phased array transmitter of a telecommunications base station with the phased array electromagnetic heater that forms the artificial ionized plasma pattern to provide in a single system for telecommunications. This simplified system has many advantages, such as lower cost and lower location expenses.

Another principal embodiment is to have the telecommunications signal power contribute to the power required to maintain the artificial ionized plasma layer.

In one example, the plasma mirror is created with a phased array heater with 500 KW of peak power and an average power of 50 KW for continued maintenance of plasma. A bi-static radar equation treats the plasma mirror as an isotropic scatterer to determine the received power at a remote receiver. With a 500 watt telecomm signal power a receiver located 22,000 meters from the array receives 3.2×10⁻⁴ watts or −32 dBm. The channel capacity is predicted to be 7×10⁷ bits per second. Point designs are also presented for a two-way communication system as well as for a plasma mirror at 30,000 meters.

Active and passive communications systems at high altitudes are currently under development. Balloons, airships, planes and helicopters are being studied and are generally referred to in this paper as High Altitude Aeronautical Platforms (HAAP). It is shown that the Integrated Plasma Mirror (IPM) is much cheaper and provides much higher signal levels at remote receiver. Additionally, the IPM is safer and can provide much higher channel capacity and bandwidth. The IPM can also be located at 30,000 meters altitude or more, providing much broader area coverage than a HAAP.

Telecommunications with the integrated plasma mirror based system is compared with that from a high altitude airship. It is shown that a plasma mirror based system can provide the same signal handling capabilities as the HAA with a plasma mirror that is roughly twice the size of the HAA.

### FIGURES

FIG. 1 Schematic Drawing of Integrated Plasma Mirror System

FIG. 2 Schematic Drawing of a High Altitude Aeronautical Platform System

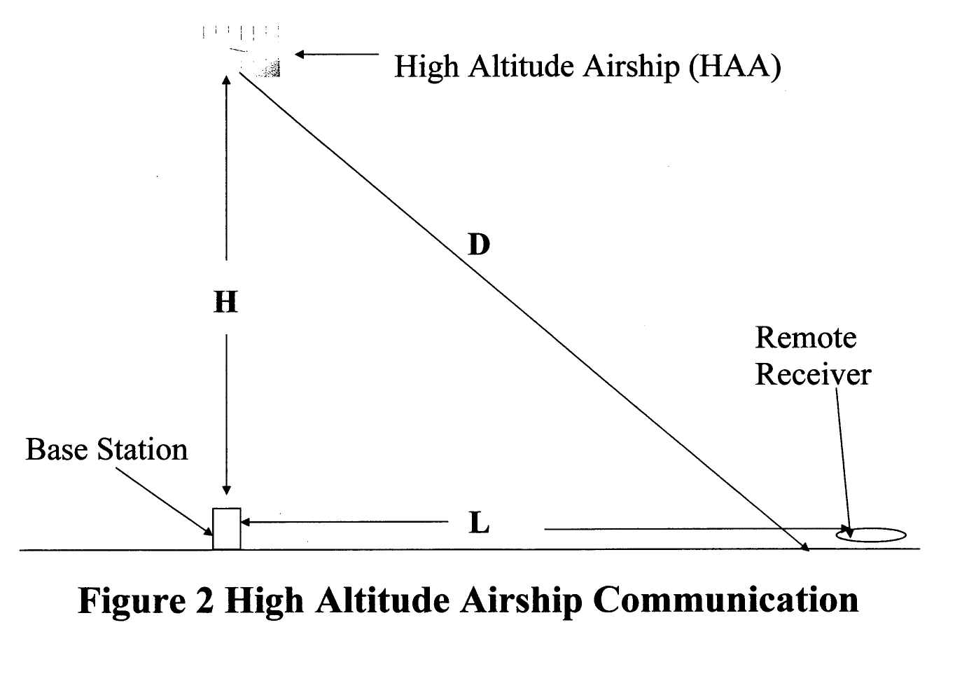

### DESCRIPTION

Overview

A new communications system is described in which the phased array heater used to create an artificial ionized plasma pattern in the atmosphere (AIPA) has an integrated phased array transmitter. By combining these two functions a simplified telecommunications system is created. The new system is called the Integrated Plasma Mirror. Another advantage is that a portion of the telecommunications signal is absorbed in the plasma pattern and contributes to the maintenance power level.

The plasma mirror is created by using the ionization trails produced in the atmosphere by cosmic rays and by meteor bursts to lower the electric field required for air breakdown below the levels in ambient air. Cosmic ray or micro-meteor trails provide ionization trails, which can locally lower the breakdown electric field in the atmosphere. It is planned to utilize this ionization source by using a high power electromagnetic wave heater to create a contiguous pattern of high electric fields (“field pattern”) in the atmosphere at a distance of between sea level and 80,000 meters and to maintain the field pattern until one or more cosmic particles such as cosmic ray electrons or micro-meteors create a columnar trail of ionized air to ignite breakdown somewhere within the field pattern. The electric fields in the field pattern accelerate the electrons in the columnar trail in all directions and produce air breakdown throughout the contiguous volume of the field pattern. The field pattern is continuously maintained during the breakdown process. The electric field intensity required for air breakdown using this method is predicted to be up to 40 times lower than the value for breakdown in ambient air and the power required is lower by a factor of up to 1600.

Once formed, the plasma pattern which is a plasma mirror can be maintained by continuously irradiating the plasma pattern with electromagnetic waves at a power level sufficient to maintain the plasma electron density at the value required by the desired application. The size or shape of the plasma pattern can be altered after it is established by changing the focal pattern and/or the power level of the electromagnetic wave generator. The physical properties of the plasma mirror such as electromagnetic wave reflectivity, electrical conductivity and electromagnetic wave absorption can be changed by varying the power level of the high power electromagnetic radiation projected from the electromagnetic wave heater which creates the contiguous pattern of high electric fields.

Point designs for the integrated plasma mirror are described and the important parameters identified. The power and equipment requirements for the system are calculated.

Telecommunications performance of the system is calculated using a modified bi-static radar equation.

### DETAILED DESCRIPTION OF METHOD AND APPARATUS FOR A TELECOMMUNICATIONS SYSTEM WITH A COMBINED BASE STATION AND PLASMA PATTERN FORMING HEATER

Integrated Plasma Mirror

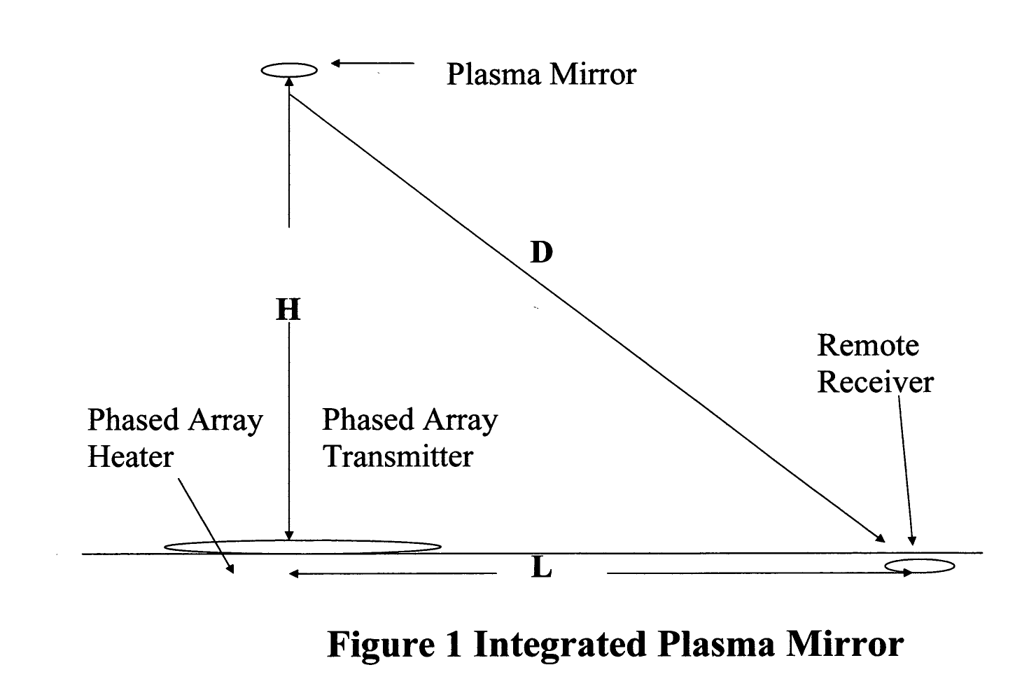

A top level description of abroad band communications utilizing passive reflection from an integrated plasma mirror system is described in FIG. 1. A phased array antenna for creation of the plasma mirror is combined with a phased array antenna for both up-link and down-link reception of signals is focused at an altitude H, to form a plasma mirror. The figure depicts a receiver located at a distance L from the combined phased arrays and a distance D, from the plasma mirror.

General Phase Array Heater Specifications

The phased array heater can be constructed with individual phased array elements driven by klystrons, gyrotrons, magnetrons or solid state oscillators. The phased array antenna elements can be parabolic dishes, slots or other radiating configurations. It is assumed that individual transmitter phased array elements are collocated with the phased array heater elements. This eliminates the need for a separate base station and ensures ease of targeting the remote plasma mirror. It is envisioned that only one or two such integrated phased arrays would be needed per metropolitan area. Large phased array receivers are being developed for cellular communications. (www.tec.org) They provide spatial, polarization and angle diversity. Signal-tracking, i.e. determining the angle-of arrival of the desired signal with a phased array can minimize the signal-to-noise plus-interference ratio in the output signal.

The power level is determined by the cosmic ignition breakdown and maintenance requirements as a function of altitude H, in the atmosphere. The power required for ignition is only applied until breakdown occurs and then the heater operates at a maintenance power level. Table 1 below summarizes the ERP requirements for ignition and the maintenance power required.

TABLE 1
COSMIC IGNITION POWER REQUIREMENTS

| Height | Cosmic | Cosmic Power | Cosmic | Maintenance |
|---|---|---|---|---|
| meters | ERP | Kilowatts/meter2 | Particle | Watts/meter2 |
| 1000 | 151 | 9500 | Electron | 5600 |
| 10000 | 139 | 66 | Electron | 560 |
| 20000 | 126 | 0.6 | Electron | 154 |
| 30000 | 132 | 1.4 | Electron | 140 |
| 40000 | 136 | 2.2 | Electron | 220 |
| 80000 | 149 | 10.6 | Meteor | 250 |

### EXAMPLE 1

### Broadcast Mode System with Plasma Mirror at an Altitude of 22000 Meters\

Point Design

The first example specifies an altitude of 22,000 meters because it is the altitude used for determination of the performance of High Altitude Aeronautical Platforms (Djuknic et al, “Establishing Wireless Communications Services via High-Altitude Aeronautical Platforms,” IEEE Communications Magazine, September, 1997.)

The power for ignition and maintenance is specified and Table 1. In this first example, the heater frequency is assumed to be 2.45 GHz and the power level for ignition P_{ignition} is assumed to be 500 KW, and the total maintenance power PT_{Maint} is 154 watts/meter². The ERP for 22,000 feet is approximately 130 and the maintenance power requirement is 154 watts/meter². The gain of the phased array heater is given by:

$${G}_{PAH} = \frac{ERP}{{P}_{ignition}} \qquad ( 1 )$$

The radius of the phased array antenna is given by:

$${R}_{PAH} = {[ \frac{{G}_{PAH} {λ}^{2}}{{π}^{2}} ]}^{0.5} \qquad ( 2 )$$

The plasma mirror radius at ignition at an altitude H, is given by the expression:

$${R}_{PM} = 1.5 [ \frac{{R}_{PAH}^{2}}{2} - \frac{λ}{2 π} {( {( \frac{π {R}_{PAH}}{λ} )}^{2} - 4 {H}^{2} )}^{0.5} ] \qquad ( 3 )$$

After ignition, the heater power is reduced to the maintenance power level and the plasma mirror area is estimated by the equation:

$${A}_{PM} = \frac{{PT}_{Maint}}{{PR}_{Maint}} \qquad ( 4 )$$

Where PR_{Maint} is the maintenance power from Table 1:

The parameters of the design basis for the broadcast example at 22,000 meters are shown in Table 2 below:

TABLE 2
Design Parameters of Broadcast Integrated Plasma
Mirror System

| Design Parameter | Value |
|---|---|
| Plasma Mirror Altitude (Meter) | 22000 |
| Phased Array Heater Power | |
| Ignition (KW) | 500 |
| Maintenance (KW) | 50 |
| Phased Array Heater Radius (Meter) | 166 |
| Phased Array Heater Area (Meter)2 | 86620 |
| Plasma Radius at Ignition (Meter) | 7.8 |
| Plasma Area at Ignition (Meter)2 | 189 |
| Heater Frequency (GHz) | 2.45 |
| Area of Plasma Mirror (Meter)2 | 325 |

Absorption and Reflection From a Plasma Mirror

The plasma parameters of the plasma mirror are determined using a numerical simulation. The peak plasma electron number density in the mirror is estimated as:

nₑ=8.3×10¹⁰ electrons/cm³ (5)

Telecommunications signals can be reflected from this layer up to 2.45 GHz. At 2.45 GHz about 80% of an incident signal is reflected and 20% absorbed by the plasma layer.

Safety in Vicinity of Phased Array Heater

The average power above the array is a function of the distance above the array: The power at the focus is roughly 82% of the total power in the array. This leaves 18% of the power in all side lobes. The flux above the array and at the edge of the array in the side lobes (assumes 3% of the power is broadcast laterally) is shown in Table 3 below.

TABLE 3
Microwave Flux in Vicinity of Phased Array

| Position | Height in meters | Flux in milliwatts/cm2 |
|---|---|---|
| Above Array | 10 | 0.05 |
| | 22000 | 15.6 |
| Side Lobes | | |
| At edge of array | 10 | 0.25 |

The recommended safety level for microwave ovens 5 cm from the door of the oven is 5 milliwatts/cm². Thus, with the exception of near the focus of the array, the levels are within those guidelines.

Communication Performance Estimates

The performance parameters of communications with a plasma mirror utilize a version of the bi-static radar equation.

$${P}_{RPM} = \frac{{P}_{TPM} {A}_{PAT} {A}_{R} {A}_{PM} ( 1 - {f}_{a} ) {M}_{PM}}{4 π {D}^{2} {H}^{2} {λ}^{2}} \qquad ( 6 )$$

Where: P_{TPM}=Transmitted power (w)
   P_{RPM}=Received power (w)
   A_{R}=Area of receiver antenna
   A_{PM}=Effective cross section of plasma mirror
   fₐ =Absosrption coefficient of plasma mirror
   D=Distance from phased array transmitter to plasma mirror
   H=Height of plasma mirror above phased array heater
   λ=Wavelength of transmitted signal
   M_{PM}=Gain of a shaped plasma mirror

The values of these parameters for broadcast mode are:
P_{TPM}=500 watts
A_{PM}=320 meter²
A_{R}=3.1 meter2
fₐ=0.2
D=31,110 meter
H=22,000 meter
λ=0.1 meter
M_{PM}=1

Ratio of Received to Transmitted Power

Using equations 6, the received power is calculated using the above parameters. It is found that the ratio of the received to transmitted power is −62 dBw or −32 dBm. This is equivalent to 4 bars on a cell phone.

Shaped Plasma Mirror

It should be noted that the value of M_{PM} can be greater than one if the plasma mirror is shaped, say in a convex shape.

Channel Capacity

The channel capacity can be estimated in bits per second using the theory of Claude Shannon as:

$${C}_{I} = Δ f {log}_{2} [ 1 + \frac{{P}_{RPM}}{{P}_{N}} ] \qquad 7$$

Where P_{RPM}=Power received from plasma mirror
   P_{N}=Received Noise Power
   Δf=Signal bandwidth in Hz

The noise received at the receiver from the thermal motion of electrons in the plasma layer is given by the following expression from Gurevich et al, Artificially Ionized Regions in the Atmosphere, Gordon and Breach Science Publishers, 1997:

$${P}_{RNPM} = \frac{2.6 * {10}^{- 19} {A}_{PM} Δ f ( \frac{T}{3000 K} )}{4 π {D}^{2} {λ}^{2}} \qquad ( 8 )$$

Where R_{RNPM} is the received noise power from the plasma mirror
   T is the electron temperature in the plasma mirror

With Δf=5×10⁶ Hz, T=3000 K
P_{RNPM}=3.4×10⁻²⁴ watts

The value of P_{N} at the receiver from the thermal environment of the receiver is given by:

$${P}_{N} = 2 {k}_{b} G Δ {fT}_{O} \\ Where {k}_{b} = 1.38 * {10}^{- 23} \frac{joule}{K} \qquad 9$$

T_{O}=Room Temperature in degrees K.
G=Receiver antenna gain

For a receiver antenna gain of 1000, P_{N}=4×10⁻¹¹ watts

### Channel Capacity for Example 1

Thus, using equation 7 with P_{RNPM}=3.2×10⁻⁴ watts the channel capacity for these broadcast mode conditions in example 1 is C_{I}=7×10⁷ bits per second.

Comparison with Qualcom-version-media-flo Broadband System

It is noted that a recent joint venture between Qualcomm, Verizon and Media-Flo for broadcast of video to cell phone users would utilize FM radio towers. In San Diego, it would give about 75% coverage of the metropolitan area. (Mountains provide obstructions). Their system will operate at a broadcast power of 50,000 watts at 715 MHz. Their channel capacity is 4.25×10⁵ bits per second.

The Integrated Plasma Mirror at an altitude of 22000 meters would close to full coverage, as mountains are not an obstruction. As seen above, at a radius of 22000 meters from the base station, the channel capacity would be 7.4×10⁷ bits per second. At a radius of 50000 meters, the channel capacity would be 6.6×10⁷ bits per second.

FCC Issues

The phased array heater is assumed to operate in the 2.45 GHz ISM band. This band is also being used for Bluetooth communication systems. Therefore, the possibility of interference will probably require approval by the FCC. Use of other frequencies for the phased array heater will also require approval. The phased array telecommunications system would utilize in licensed bands. For example, the new Qualcomm-Verizon-Media-Flo broadband system has licensed UHF channel 55 at 715 MHz. That license could most likely be used to reflect that same wavelength off the plasma mirror.

### EXAMPLE 2

### Two-way Communication with Plasma Mirror at 22000 Meters

Point Design

The plasma mirror design parameters are the same as shown in Table 1 for a broadcast system, with the same plasma mirror properties.

Two-way Communications Performance Estimates

It is assumed that the remote communication device is located at a distance of 22,000 meters from the base station phased array facility. It is also assumed that the remote communication device has a gain of 2 and a transmit power level of 5 watts (similar to a cell phone) and the transmit power from the base station is 5 watts at a frequency of 2.45 GHz.

Using equation 6, it is found that the ratio of transmitted to received power for communications link is −91 dBm. This is in the range of 1 bar on a cell phone. The channel capacity is 1.38×10⁵ bits per second.

The base station phased array transmitter/receiver can be designed to adequately process such signal levels. Another mode of two-way operation is to have the base station transmit at higher power levels. At a power level of 500 watts the signal at the remote device would be −71 dBm with a channel capacity of 7.6×10⁶ bits per second. This is in the range of two bars on a cell phone.

### EXAMPLE 3

### Broadcast Mode System With a Plasma Mirror at an Altitude of 30000 Meters

Point Design

The parameters of the design are shown in Table 4. The ignition power and maintenance power for the plasma mirror have been increased by a factor of 2 over example 1 to compensate for the increased altitude.

TABLE 4
Design Parameters for Plasma Mirror at Altitude of
30,000 Meters

| Design Parameter | Value |
|---|---|
| Plasma Mirror Altitude (Meter) | 30000 |
| Phased Array Heater Power | |
| Ignition (KW) | 1000 |
| Maintenance (KW) | 100 |
| Phased Array Heater Radius (Meter) | 160 |
| Phased Array Heater Area (Meter)2 | 80000 |
| Plasma Radius at Ignition (Meter) | 11 |
| Plasma Area at Ignition (Meter)2 | 378 |
| Heater Frequency (GHz) | 2.45 |
| Area of Plasma Mirror (Meter)2 | 714 |

Absorption and Reflection of Communications Signals

The plasma parameters of the plasma mirror are determined using a numerical simulation. The peak plasma electron number density in the mirror is estimated as:

nₑ=8.3×10¹⁰ electrons/cm³ (5)

Telecommunications signals can be reflected from this layer up to 2.45 GHz. At 2.45 GHz about 80% of an incident signal is reflected and 20% absorbed by the plasma layer.

Safety

The microwave flux above the array and at its edges is shown in Table 5.

TABLE 5
Safety Parameters for Example 3

| Position | Height in meters | Flux in milliwatts/cm2 |
|---|---|---|
| Above Array | 10 | 0.1 |
| | 30000 | 15.6 |
| Side Lobes | | |
| At edge of array | 10 | 0.5 |

Broadcast Performance Estimates

The input parameters to Equation 6 are as follows:
P_{TPM}=500 watts
A_{PM}=714 meter²
A_{R}=3.1 meter2
fₐ=0.2
D=42,400 meter
H=30,000 meter
λ=0.1 meter
M_{PM}=1

The ratio of received to transmitted power is −34 dBm and the channel capacity is 6.5×10⁷ bits per second.

Comparison With High Altitude Aeronautical Platforms

Reviews of the advantages of use of artificial ionized plasma patterns in the atmosphere for military and civilian applications have raised the issue of their comparison with High Altitude Aeronautical Platform (HAAP) embodiments. The U. S. Government is funding two major projects in the high altitude aeronautical platform arena. The first is sponsored by the U. S. Army Space and Missile Defense Command and is called the Composite Hull High Altitude Powered Platform (CHHAPP). This aircraft is also sometimes referred to as the HiSentinel High-Altitude Airship. The second project is being sponsored by DARPA and is called the high-altitude airship (HAA). In 2005, DARPA awarded a contract for nearly $150 million to Lockheed-Martin for prototype development. First flight of the HAA is planned for 2008.

There are also three private companies funding working on high altitude airships. Sanswire is developing high altitude airships they call “Stratellites” and Techsphere is developing a high altitude version of their spherically shaped airships. JP Aerospace is looking at airships for lifting cargo into low earth orbit.

A comparison of the performance of an HAA with a plasma mirror with both platforms at the same altitude of 22,000 meters for various issues is shown in Table 6.

TABLE 6
Comparison of Plasma Mirror Communication System with High Altitude

| Issue | High Altitude Airship | Plasma Mirror |
|---|---|---|
| Development Cost | 147 M | 5.5 M |
| Operating Cost | Needs terrestial terminal | Needs terrestial location |
| | and expensive on board | with large area and |
| | solar generated power | phased array heater |
| | of 0.5 Mw | power of 0.27 to 2.7 Mw |
| Power Requirements | Needs 0.5 Mw available | Needs phased array |
| | for maneuvering and | heater power of 0.27 to |
| | station keeping | 2.7 Mw |
| Size at Operating | 6280 meter² | 17480 meter2 |
| Altitude | | |
| Breadth of Geographical Coverage | Hundreds of kilometers | Hundreds of kilometers |
| | per platform | per platform |
| System Growth | Multiple platforms | Single plasma mirror |
| | required for dense | can handle dense |
| | coverage areas | coverage area |
| System complexity due to motion of | Motion low to moderate | Phased array heater |
| components | (stability characteristics | and transmitter and |
| | to be proven.) | focal region stationary |
| Shadowing from Terrain | Problem only for low | Problem only for low |
| | look angles | look angles |
| Communications and | Single gateway collects | Single gateway collects |
| power infrastructure; real estate | traffic from a large area | traffic from a large area |
| Aesthetic issues and | Earth stations located | Base station can be |
| health concerns with | away from populated | located safely in |
| towers and antennas | areas | populated area |
| Public Safety Concerns | Large aircraft floating or | Microwave flux above |
| | flying overhead can | and on the perimeter of |
| | raise significant | phased array heater |
| | objections | less than or equal to |
| | | home oven microwave |
| | | safety guidelines |

The path loss of the up-link from a base station or a remote receiver to a high altitude airship is compensated for by amplification of the signal on the airship.

The down-link signals can be described by equation 10 below:

$${P}_{RHAA} = \frac{{P}_{THAA} {A}_{HAA} {A}_{R}}{4 π {D}^{2} {λ}^{2}} \qquad ( 10 )$$

Where: P_{THAA}=Transmitted power from HAA
A_{HAA}=Area of antenna on HAA

The ratio of the received power level from a Plasma Mirror (equation 6) and from a transmitter on an HAA (equation 10) is as follows:

$$\frac{{P}_{RPM}}{{P}_{RHAA}} = \frac{{P}_{TPM} {A}_{PAT} {A}_{PM} ( 1 - {f}_{a} ) {M}_{PM}}{{P}_{THAA} {A}_{HAAT} {H}^{2}} \qquad ( 11 )$$

Where: P_{THAA}=Transmitted power from HAA
   A_{HAAT}=Effective area of HAA antenna

According to Djuknic et al, in “Establishing Wireless Communications Services via High-Altitude Aeronautical Platforms,” IEEE Communications Magazine, September, 1997, a typical value for the gain of an on-board transmitter antenna is about 35. This would give a value for A_{HAAT} of 2.5 meter².

If the transmitted power from each system is the same, then the ratio of the received signals is unity when A_{PM}=1.7×10⁴ meter². To establish an area of this size, the maintenance power of the phased array heater would be 2.7 Mw. (With M_{PM}=1) The Lockheed HAA will have a cross section of 152 meters×45 meters or 6.8×10³ meter² and will require a power availability of 0.5 Mw. (For station keeping and for the payload)

The maintenance power of the plasma mirror can be lowered by shaping the layer to have a net gain. With a value of M_{PM}=10, the maintenance power would only need to be 275 Kw for equivalent performance.

The plasma mirror embodiment can have performance equal to an HAA in two-way communication and far exceed its channel capacity in broadcast mode because of the higher power available to the ground based system.

1. A method of providing a broadcast communication system that comprises:
a. A phased array heater antenna for beaming electromagnetic waves that are focused at an altitude H, in the atmosphere to create an ionized plasma pattern and,
b. A remote receiver that is located at a distance L, from the phased array heater antenna, and,
c. A base station which is a phased array antenna collocated with the phased array heater antenna to direct the transmission of telecommunication signals to reflect of f the ionized plasma pattern.
Wherein the telecommunications signal is aimed precisely at the plasma pattern which reflects the electromagnetic waves of the telecommunication signal isotropically with a portion received at the remote receiver.

2. The method of claim 1 wherein the phased array transmitter radiating elements utilize the same antenna as the phased array elements of the heater antenna.

3. The method of claim 1 wherein the frequency of the electromagnetic waves for creating the plasma pattern is the same as the telecommunication signal.

4. The method of claim 1 wherein the frequency of the electromagnetic waves of the telecommunication signal are less than the frequency of the electromagnetic wave heater phased array.

5. The method of claim 1 wherein the phased array heater elements and the telecommunication elements are separate units but co-located in the same area.

7. The method of claim 1 wherein the heater power and the telecommunications power are added together to provide the maintenance power for the plasma pattern.
